(19) United States
(12) Patent Application Publication
(10) Pub. No.: US 2008/0030952 A1
(43) Pub. Date: Feb. 7, 2008

(54) Heat dissipating module and its fan and housing

(75) Inventors: Chin-Ming Chen, Taoyuan Hsien (TW); Yuhsien Lin, Taoyuan Hsien (TW); Tsung-Lin Chen, Taoyuan Hsien (TW); Alex Hsia, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/606,072

(22) Filed: Nov. 30, 2006

(30) Foreign Application Priority Data
Aug. 2, 2006 (TW) 095128336

(51) Int. Cl. H05K 7/20

(52) U.S. Cl. 361/697

(57) ABSTRACT

A heat dissipating module has a fan and at least one heat sink contacting with a heat source. The fan has an impeller and a housing. The housing has a base for supporting the impeller, at least one rib extending from the edge of the base to the backward direction of the center of the base, at least one sidewall, an annular wall connecting with the rib and/or the sidewall, at least one protrusion axially protruding from the annular wall and/or the sidewall, at least one securing member disposed on the end of the protrusion, and at least one fastener disposed in the securing member. The base, the rib, the sidewall, the annular wall, the protrusion, and the securing member are integrally formed as a single piece. The protrusion has at least one block structure for fixing the heat sink to the housing.

### CROSS REFERENCE TO RELATED APPLICATIONS

This Non-provisional application claims priority under 35 U.S.C. §119(a) on Patent Application No(s). 095128336 filed in Taiwan, Republic of China on Aug. 2, 2006, the entire contents of which are hereby incorporated by reference.

### BACKGROUND OF THE INVENTION

1. Field of Invention

The invention relates to a heat dissipating module, a fan and a housing thereof, and, in particular, to a heat dissipating module, a fan of the heat dissipating module, and a housing of the fan with a high yield, a low cost and a reduced number of manufacturing processes.

2. Related Art

In a present electronic device, a central processor unit (CPU) is typically used as an operating processor core of the electronic device. However, the heat generated by the CPU greatly increases as the processing speed of the CPU is getting higher and higher. The heat has to be quickly removed using a heat dissipating module containing a fan and a heat sink.

As shown in FIG. 1, a conventional heat dissipating module 200 is composed of several separated members. That is, the conventional heat dissipating module 200 is formed by a fan 202, a heat sink 204, a metallic X-clip 206 and four fixing pins 208. The conventional heat dissipating module 200 is assembled as follows. First, the fan 202 is embedded onto a top surface of the heat sink 204. Next, the X-clip 206 is aligned with and fixed onto a bottom surface of the heat sink 204 by way of aligned clamping or riveting. Thereafter, the fixing pins 208 are accommodated in the periphery of the X-clip 206 to form the heat dissipating module.

In this structure, however, at least two aligned connections, which include at least one aligned connection between the fan and the heat sink and at least one aligned clamping or riveting between the heat sink and the X-clip, have to be made. The aligned clamping or riveting between the heat sink and the X-clip must be made very precisely. As long as the heat sink and the X-clip are not precisely aligned, the heat dissipating module and the to-be-dissipated heat source will be loosened or cannot contact each other closely.

Consequently, the conventional heat dissipating module has the increased number of assembling processes and the lengthened assembling time, and the product yield is decreased and the manufacturing cost is increased due to the insufficient precision.

### SUMMARY OF THE INVENTION

In view of the foregoing, the invention is to provide a heat dissipating module, a fan and a housing, which may be assembled with the reduced number of processes and the reduced manufacturing cost.

In addition, the invention is to provide a heat dissipating module with a better heat dissipating efficiency and a greatly increased product yield.

To achieve the above, the invention discloses a heat dissipating module including at least one heat sink and a fan. The heat sink is connected with a heat source. The fan includes an impeller and a housing. The housing includes a base, at least one rib, at least one sidewall, an annular wall, at least one protrusion, at least one securing member and at least one fastener. The base supports the impeller. The rib is connected with a periphery of the base and extends in a direction away from a center of the base. The sidewall is correspondingly connected with the rib to make the rib be located between the sidewall and the base. The annular wall is connected with the sidewall or the rib. The protrusion axially protrudes from the base and has at least one first block structure for fixing the heat sink to the housing. The securing member is disposed at one end of the protrusion. The base, the rib, the sidewall, the annular wall, the protrusion and the securing member are integrally formed as a single piece. The fastener is accommodated in the securing member.

To achieve the above, the invention also discloses a heat dissipating module including at least one heat sink and a fan. The heat sink is connected with a heat source. The fan includes an impeller and a housing. The housing includes a base, at least one protrusion, at least one securing member and at least one fastener. The base has at least one air flow input/output opening for supporting the impeller. The protrusion axially protrudes from the base and has at least one first block structure to enable the heat sink to be fixed to the housing. The securing member is disposed at one end of the protrusion. The base, the protrusion and the securing member are integrally formed as a single piece. The fastener is accommodated in the securing member.

To achieve the above, the invention discloses a fan including an impeller and a housing. The housing includes a base, at least one rib, at least one sidewall, an annular wall, at least one protrusion, at least one securing member, and at least one fastener. The base supports the impeller. The rib is connected with a periphery of the base and extends in a direction away from a center of the base. The sidewall is correspondingly connected with the rib to make the rib be located between the sidewall and the base. The annular wall is connected with the sidewall or the rib. The protrusion axially protrudes from the base. The securing member is disposed at one end of the protrusion. The base, the rib, the sidewall, the annular wall, the protrusion and the securing member are integrally formed as a single piece. The fastener is accommodated in the securing member.

To achieve the above, the invention also discloses a fan including an impeller and a housing. The housing includes a base, at least one securing member, and at least one fastener. The base has at least one air flow input/output opening for supporting the impeller. The securing member is connected with the base. The fastener is accommodated in the securing member. The housing is fixed to or separated from a system through the fastener.

To achieve the above, the invention discloses a housing including a base, at least one rib, at least one sidewall, an annular wall, at least one protrusion, at least one securing member, and at least one fastener. The base supports an impeller. The rib is connected with a periphery of the base and extends in a direction away from a center of the base. The sidewall is correspondingly connected with the rib, and the rib is located between the sidewall and the base. The annular wall is connected to the sidewall or the rib. The protrusion axially protrudes from the base. The securing member is disposed at one end of the protrusion. The base, the rib, the sidewall, the annular wall, the protrusion and the securing member are integrally formed as a single piece. The fastener is accommodated in the securing member.

To achieve the above, the invention also discloses a housing including a base, at least one securing member, and a fastener. The base, accommodating an impeller, has at least one air flow input/output opening. The securing member is connected with the base. The base and the securing member are integrally formed as a single piece. The fastener is accommodated in the securing member. The housing is fixed to or separated from a system through the fastener.

In the heat dissipating module of the invention, the housing is an integrally formed structure and has at least one fastener. Thus, the heat dissipating module can be rapidly and precisely connected with or separated from the heat source of a system without using additional metallic X-clip. As a result, the number of steps in assembling the module and the manufacturing cost can be greatly reduced, and the product yield can be greatly enhanced.

### BRIEF DESCRIPTION OF THE DRAWINGS

The invention will become more fully understood from the detailed description given herein below illustration only, and thus is not limitative of the present invention, and wherein:

FIG. 1 is a pictorial view showing a conventional heat dissipating module;

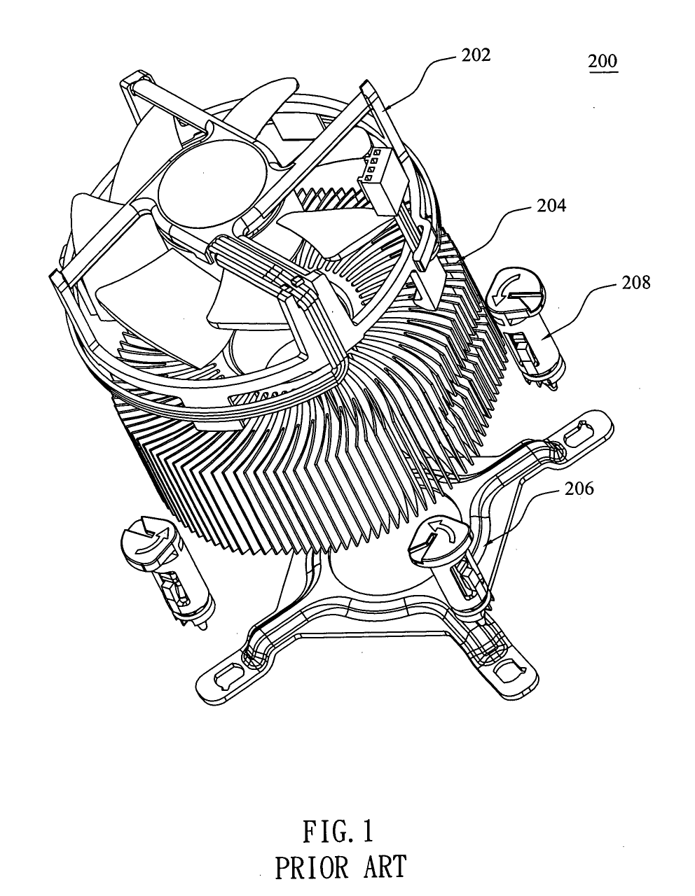

FIG. 2 is a pictorial view showing a heat dissipating module according to a preferred embodiment of the invention;

FIG. 3 is a pictorial view showing a fan according to the preferred embodiment of the invention; and

FIG. 4 is a front view of FIG. 3.

### DETAILED DESCRIPTION OF THE INVENTION

The present invention will be apparent from the following detailed description, which proceeds with reference to the accompanying drawings, wherein the same references relate to the same elements.

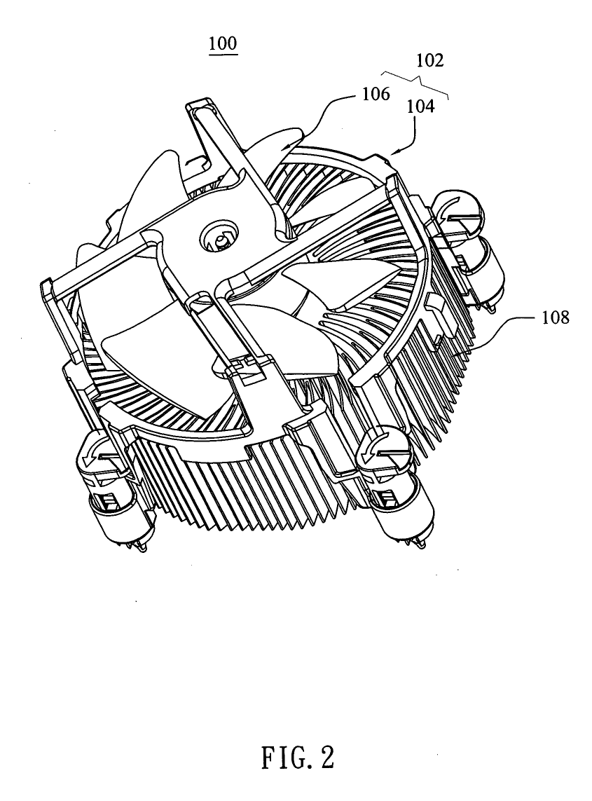

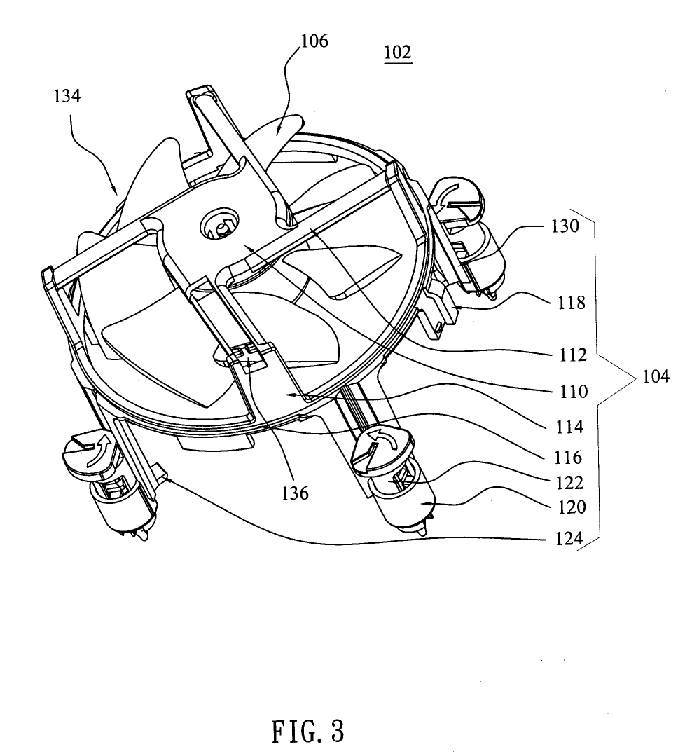

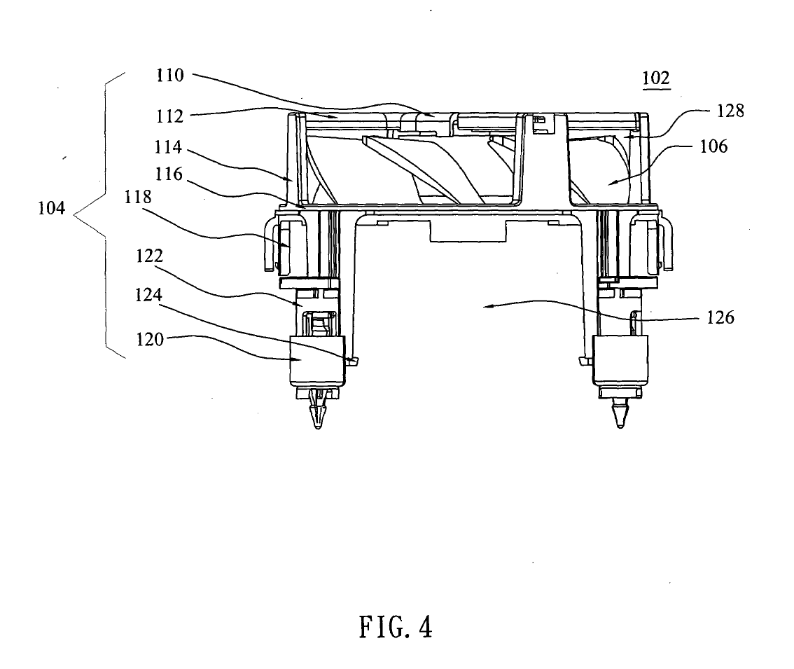

FIG. 2 is a pictorial view showing a heat dissipating module according to a preferred embodiment of the invention. FIG. 3 is a pictorial view showing a fan according to the preferred embodiment of the invention. FIG. 4 is a front view of FIG. 3.

Referring simultaneously to FIGS. 2 to 4, the heat dissipating module includes at least one heat sink 108 and a fan 102. The fan 102 includes an impeller 106 and a housing 104.

The heat sink 108 is a thermo-conductive structure and may be made of a metallic material or any heat conductive material. The axial cross section of the heat sink 108 may have a circular shape, a polygonal shape, an elliptic shape or any other irregular shape. The heat sink 108 preferably has a thermo-conductive surface on a center line of the heat sink 108. The heat sink 108 may be connected with a heat source through the thermo-conductive surface. The heat source may be an electronic element such as a central processor unit.

The impeller 106 is connected with the housing 104 and driven by a motor. At least one blade of the impeller 106 may be an axial flowing type blade, a centrifugal type blade, or a flat type blade.

The housing 104 has a base 110, at least one protrusion 130, at least one securing member 120 and at least one fastener 122. The base 110, the protrusion 130 and the securing member 120 are integrally formed as a single piece.

The housing 104 further has at least one rib 112, at least one sidewall 114 and an annular wall 116. The axial cross section of the base 110 may have a circular shape or a polygonal shape. The base 110 has a plate structure, a mesh structure or a strip structure. In addition, the base 110 supports the impeller 106.

The rib 112 is connected with a periphery of the base 110 and extends in a direction away from a center of the base 110. The rib 112 and the base 110 are preferably located on the same plane. The rib 112 may be a strip structure, a stationary blade structure, a plate structure or a mesh structure. The rib 112 may be formed with a wire slot 136 for guiding wires of the fan.

The sidewall 114 is correspondingly connected with the rib 112 to make the rib 112 be located between the sidewall 114 and the base 110. The sidewall 114 may be a strip structure, a plate structure, a curved plate structure, a mesh structure or an annular structure, wherein those structures can be parallel with the center line of the housing 104. In addition, the sidewall 114 may be formed with a pattern to glorify the housing 104, reduce the material usage and enhance the tensile strength of the sidewall 114.

The annular wall 116 is connected with the sidewall 114 or the rib 112 to enhance the tensile strength of the housing 104 and keep the shape of the housing 104. The annular wall 116 may be an annular structure, an arc-type structure or a C-type structure. The axial cross section of the annular wall 116 may be a circular shape, an elliptic shape, a polygonal shape, a C shape or an arc shape.

The base 110, the rib 112, the sidewall 114 and the annular wall 116 constitute at least one air flow input/output opening 134. In addition, the base 110, the rib 112, the sidewall 114 and the annular wall 116 also enclose a chamber 128, in which the impeller 106 is accommodated.

The protrusion 130 protrudes from the base 110, the annular wall 116 or the sidewall 114. For example, the protrusion 130 may axially extend outwardly from the annular wall 116 or the sidewall 114. The protrusion 130 has at least one block structure 124 for enabling the heat sink 108 to the housing 104. Furthermore, the block structure 124 protrudes from the protrusion 130 toward the center line of the housing 104. The block structure 124 may be a projecting block, an inverse hook or a tongue.

The securing member 120 is connected with the base 110, the rib 112, the sidewall 114, the annular wall 116 or one end of the protrusion 130 distant from the base 110 for accommodating the fastener 122. In addition, the securing member 120 may also be connected with a middle section of the protrusion 130, or one end of the protrusion 130 close to the base 110. The securing member 120 may have a cylindrical structure.

In addition, the base 110, the rib 112, the sidewall 114, the annular wall 116, the protrusion 130 and the securing member 120 are integrally formed as a single piece. The housing 104 (i.e., the base 110, the rib 112, the sidewall 114, the annular wall 116, the protrusion 130 and the securing member 120) may be made of a metallic material or a plastic material.

The fastener 122 is movably accommodated in the securing member 120. The fastener 122 fastens the housing 104 to an external system or separates the housing 104 from the external system. The fastening/separating operation is made by rotating, pressing or stretching the fastener 122. For example, when the housing 104 is placed on the external system, the fastener 122 is rotating a predetermined angle (e.g., 90 degrees) to expand the bottom of the fastener 122 and then the housing 104 is fastened to the external system. Thereafter, the fastener 122 is reversed with another predetermined angle (e.g., −90 degrees) to shrink the bottom of the fastener 122 and the housing 104 is separated from the external system. The fastener 122 is made of a plastic material or a metallic material, and the fastener 122 cannot be separated from the securing member 120.

In addition, the housing 104 may further include at least one block structure 118, which extends and protrudes from the base 110, the rib 112, the sidewall 114 or the annular wall 116. For example, the block structure 118 axially extends and protrudes from the annular wall 116. The block structure 118 and the protrusion 130 define a space 126 to allow the heat sink 108 to be disposed therein. The space 126 may correspond to the shape of the heat sink 108. The block structure 118 further includes a clamping slot for clamping a wire.

In the heat dissipating module of the invention, the housing is an integrally formed structure and has at least one fastener. Therefore, the heat dissipating module can be rapidly and precisely connected with or separated from the heat source of a system without using additional metallic X-clip. Accordingly, the number of steps in assembling the module and the manufacturing cost can be greatly reduced, and the product yield can be greatly enhanced.

In the heat dissipating module of the invention, the housing is an integrally formed structure and has at least one fastener. Thus, the heat dissipating module can be rapidly and precisely connected with or separated from the heat source of a system without using additional metallic X-clip. As a result, the number of steps in assembling the module and the manufacturing cost can be greatly reduced, and the product yield can be greatly enhanced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A heat dissipating module, comprising:
at least one heat sink; and
a fan coupled to the heat sink and comprising an impeller and a housing, wherein the housing comprises:
a base having at least one air flow input/output opening for supporting the impeller;
at least one securing member connected with the base; and
at least one fastener accommodated in the securing member, wherein the housing is fixed to or separated from a system through the fastener.

2. The heat dissipating module according to claim 1, wherein the base has a plate structure, a mesh structure, or a strip structure.

3. The heat dissipating module according to claim 1, wherein the housing farther comprises at least one rib extending in a direction away from a center of the base.

4. The heat dissipating module according to claim 3, wherein the rib is a strip structure, a stationary blade structure, a plate structure or a mesh structure.

5. The heat dissipating module according to claim 3, wherein the housing further comprises at least one sidewall correspondingly connected with the rib.

6. The heat dissipating module according to claim 5, wherein the sidewall is a strip structure, a plate structure, a curved plate structure, a mesh structure or an annular structure.

7. The heat dissipating module according to claim 5, wherein the sidewall has a pattern.

8. The heat dissipating module according to claim 5, wherein the housing further comprises an annular wall connected with the sidewall or the rib.

9. The heat dissipating module according to claim 8, wherein an axial cross section of the annular wall has a circular shape, an elliptic shape, a polygonal shape, a C shape or an arc shape.

10. The heat dissipating module according to claim 1, wherein the housing comprises at least one protrusion protruding from the base, the protrusion has at least one first block structure for fixing the heat sink to the housing.

11. The heat dissipating module according to claim 10, wherein the protrusion axially extends from the annular wall outwardly.

12. The heat dissipating module according to claim 10, wherein the securing member is connected with one end of the protrusion distant from the base, a middle section of the protrusion or one end of the protrusion close to the base.

13. The heat dissipating module according to claim 10, wherein the base, the securing member and the protrusion are integrally formed as a signal piece.

14. The heat dissipating module according to claim 1, wherein the fastener is fastened to or separated from the system by rotating, pressing or stretching the fastener.

15. The heat dissipating module according to claim 1, wherein the housing further comprises at least one second block structure protruding from the base for defining a space to allow the heat sink to be disposed therein.

16. The heat dissipating module according to claim 15, wherein the second block structure has a clamping slot for clamping a wire.

17. The heat dissipating module according to claim 1, wherein the heat sink has an axial cross section with a circular shape, a polygonal shape, an elliptic shape or any irregular shapes.

18. A fan, comprising:
an impeller; and
a housing comprising:
a base having at least one air flow input/output opening for supporting the impeller;
at least one securing member connected with the base; and
at least one fastener accommodated in the securing member, wherein the housing is fixed to or separated from a system through the fastener.

19. The heat dissipating module according to claim 18, wherein the housing comprises at least one protrusion protruding from the base, the protrusion has at least one first block structure for fixing the heat sink to the housing.

20. A housing, comprising:
a base having at least one air flow input/output opening;
at least one securing member connected with the base; and
at least one fastener accommodated in the securing member; wherein the housing is fixed to or separated from a system through the fastener.
